(19) United States
(12) Patent Application Publication
(10) Pub. No.: US 2026/0293348 A1
(43) Pub. Date: Sep. 24, 2026

(54) PHOTOELECTRIC CONVERSION DEVICE

(71) Applicant: CANON KABUSHIKI KAISHA, Tokyo (JP)

(72) Inventors: DAIKI SHIRAHIGE, Kanagawa (JP); SHINYA ICHINO, Saitama (JP)

(21) Appl. No.: 19/556,553

(22) Filed: Mar. 4, 2026

(30) Foreign Application Priority Data
Mar. 21, 2025 (JP) 2025-046643

(51) Int. Cl. H10F 39/00; H04N 25/77; H10F 39/18

(52) U.S. Cl. CPC H10F 39/8063; H04N 25/77; H10F 39/182

(57) ABSTRACT

A photoelectric conversion device includes a microlens, and a plurality of pixels that share the microlens. The plurality of pixels include a first pixel having a first sensitivity, a second pixel having the first sensitivity, a third pixel having a second sensitivity different from the first sensitivity, and a fourth pixel having the second sensitivity, and the first pixel and the second pixel are arranged with point symmetry with respect to an optical axis of the microlens. A phase difference is detected by using a pair of a signal output from the first pixel and a signal output from the second pixel, and a phase difference is detected by using a pair of a signal output from the third pixel and a signal output from the fourth pixel.

### BACKGROUND

### Field of the Technology

The present disclosure relates to a photoelectric conversion device, and particularly relates to an imaging device that is compatible with an image plane phase difference auto-focus (AF).

### Description of the Related Art

A technique has been developed for detecting a phase difference by disposing a plurality of photoelectric conversion elements corresponding to one microlens in a photoelectric conversion device. The illuminance range in which the phase difference can be detected is determined by noise and a full well capacity that can be accumulated in each photoelectric conversion element.

In Japanese Patent Laid-Open No. 2015-201834, it is proposed to ensure compatibility between the generation of a pixel signal having a high dynamic range and the generation of phase difference information by configuring the photoelectric conversion elements of pixels disposed for one microlens with a sensitivity difference.

However, in the technique of Japanese Patent Laid-Open No. 2015-201834, the phase difference detection accuracy on the low-intensity side can be improved by increasing the sensitivity of each photoelectric conversion element for detecting a phase difference, whereas the phase difference detection limit is lowered by reducing the illuminance, at which the saturation charge is reached, according to improvement in sensitivity.

### SUMMARY

Accordingly, the present disclosure provides a technique capable of extending the illuminance range in which a phase difference can be detected in a photoelectric conversion device configured with a plurality of pixels corresponding to one microlens.

According to some embodiments, a photoelectric conversion device includes a microlens, and a plurality of pixels that share the microlens, wherein the plurality of pixels include a first pixel having a first sensitivity, a second pixel having the first sensitivity, a third pixel having a second sensitivity different from the first sensitivity, and a fourth pixel having the second sensitivity, the first pixel and the second pixel are arranged with point symmetry with respect to an optical axis of the microlens, a phase difference is detected by using a pair of a signal output from the first pixel and a signal output from the second pixel, and a phase difference is detected by using a pair of a signal output from the third pixel and a signal output from the fourth pixel.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram showing an imaging device according to a first embodiment.

FIG. 2 is a plan view showing the pixels of the imaging device according to the first embodiment.

FIG. 3 is a plan view showing the sensitivity of the pixels of the imaging device according to the first embodiment.

FIG. 4A shows the pixels of the imaging device according to the first embodiment, and FIG. 4B is a cross-sectional view of FIG. 4A.

FIG. 5A shows the pixels of the imaging device according to the first embodiment, and FIG. 5B is a cross-sectional view of FIG. 5A.

FIG. 6 is an equivalent circuit diagram showing the pixels of the imaging device according to the first embodiment.

FIG. 7 shows the arrangement of the pixels and the microlens of the imaging device according to the first embodiment.

FIG. 8 shows the arrangement of the pixels and the microlens of the imaging device according to a first modification example.

FIG. 9 shows the arrangement of the pixels and the microlens of the imaging device according to a second modification example.

FIG. 10 shows the arrangement of the pixels and the microlens of the imaging device according to a third modification example.

FIG. 11 shows the arrangement of the pixels and the microlens of the imaging device according to a fourth modification example.

FIG. 12 shows the arrangement of the pixels and the microlens of the imaging device according to a fifth modification example.

FIG. 13 shows the arrangement of the pixels and the microlens of the imaging device according to a sixth modification example.

FIG. 14 shows the arrangement of the pixels and the microlens of the imaging device according to a seventh modification example.

FIG. 15 shows the arrangement of the pixels and the microlens of the imaging device according to an eighth modification example.

FIG. 16 shows the configuration of the pixel array of an imaging device according to a second embodiment.

FIG. 17 shows the configuration of the pixel array of the imaging device according to a ninth modification example.

FIG. 18 is an explanatory drawing showing a photoelectric conversion system according to a third embodiment.

FIGS. 19A and 19B are explanatory drawings showing a photoelectric conversion system and a mobile body according to a fourth embodiment.

FIG. 20 is an explanatory drawing showing a distance image sensor according to a fifth embodiment.

FIG. 21 is an explanatory drawing showing an endoscope surgical system according to a sixth embodiment.

FIGS. 22A and 22B are explanatory drawings showing smart glasses according to a seventh embodiment.

FIGS. 23A and 23B are explanatory drawings showing an electronic device according to an eighth embodiment.

FIG. 24 is an explanatory drawing showing an X-ray CT device according to a ninth embodiment.

FIG. 25 is an explanatory drawing showing a system according to a tenth embodiment.

### DESCRIPTION OF THE EMBODIMENTS

The following modes are intended to embody the technical idea of the present disclosure, and do not limit the present disclosure. Sizes of and positional relationships between members shown in the drawings may be exaggerated to clarity the description. In the following description, the same components are denoted by the same reference numerals, and descriptions thereof may be omitted.

Hereinbelow, referring to the drawings, embodiments of the present disclosure will be described in detail. In the following description, terms which indicate specific directions or positions (e.g., "up", "down", "right”, "left", and other terms including such terms) are used as necessary. Such terms are used for ease of understanding of the embodiments with reference to the drawings, and are not intended to limit the technical scope of the present disclosure by the meanings of the terms.

In the present specification, a plan view is a view from a direction perpendicular to the light incident surface of a semiconductor layer. Furthermore, a cross-sectional view is a view from a direction perpendicular to the light incident surface of the semiconductor layer. In the case where the light incident surface of the semiconductor layer is coarse as viewed microscopically, a plane view is defined with reference to the light incident surface of the semiconductor layer viewed macroscopically.

### First Embodiment

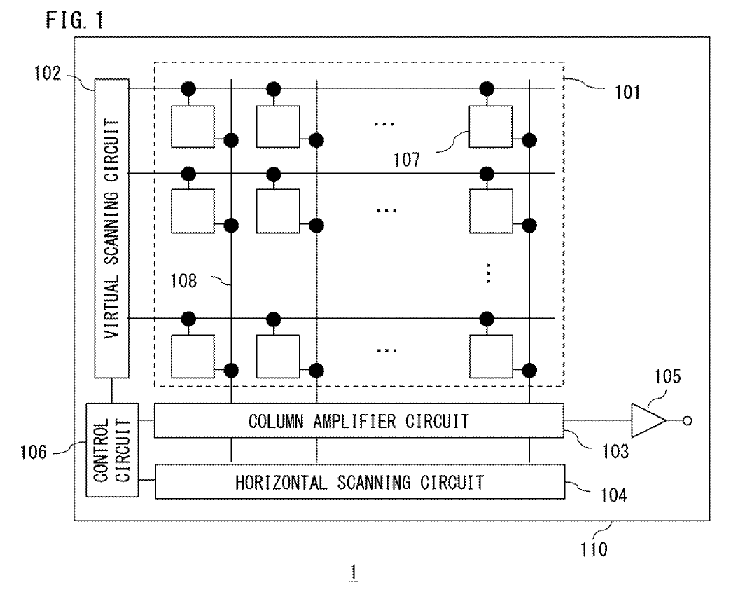

Referring to FIGS. 1 to 9, an imaging device according to a first embodiment of the present disclosure will be described below. FIG. 1 is a block diagram showing the schematic configuration of an imaging device 1 according to the present embodiment. As shown in FIG. 1, the imaging device 1 includes a pixel array 101, a vertical scanning circuit 102, a column amplifier circuit 103, a horizontal scanning circuit 104, an output circuit 105, and a control circuit 106. The imaging device 1 is a photoelectric conversion device formed on a semiconductor substrate such as a silicon substrate. The imaging device 1 is, for example, a complementary metal-oxide semiconductor (CMOS) image sensor.

The pixel array 101 includes a plurality of pixels 107 arranged in a two-dimensional array including multiple rows and multiple columns on a semiconductor substrate 110. The vertical scanning circuit 102 supplies, to the pixels 107, a control signal for controlling the transistors of the pixels 107 to an on-state (conducting state) or an off-state (non-conducting state). A column signal line 108 is provided for each column of the pixel array 101, and signals from the pixels 107 are read into the column signal line 108 for each column. The column amplifier circuit 103 amplifies the pixel signals output to the column signal line 108 and performs correlation double sampling processing or the like on the basis of the signal at the time of resetting the pixel 107 and the signal at the time of photoelectric conversion. The horizontal scanning circuit 104 supplies, to the column amplifier circuit 103, a control signal for turning on or off a switch connected to the amplifier of the column amplifier circuit 103.

The control circuit 106 controls the vertical scanning circuit 102, the column amplifier circuit 103, and the horizontal scanning circuit 104. The output circuit 105 includes a buffer amplifier and a differential amplifier and outputs a pixel signal from the column amplifier circuit 103 to a signal processing unit outside the imaging device. The imaging device 1 may further include an AD conversion unit for outputting a digital pixel signal to an external signal processing unit.

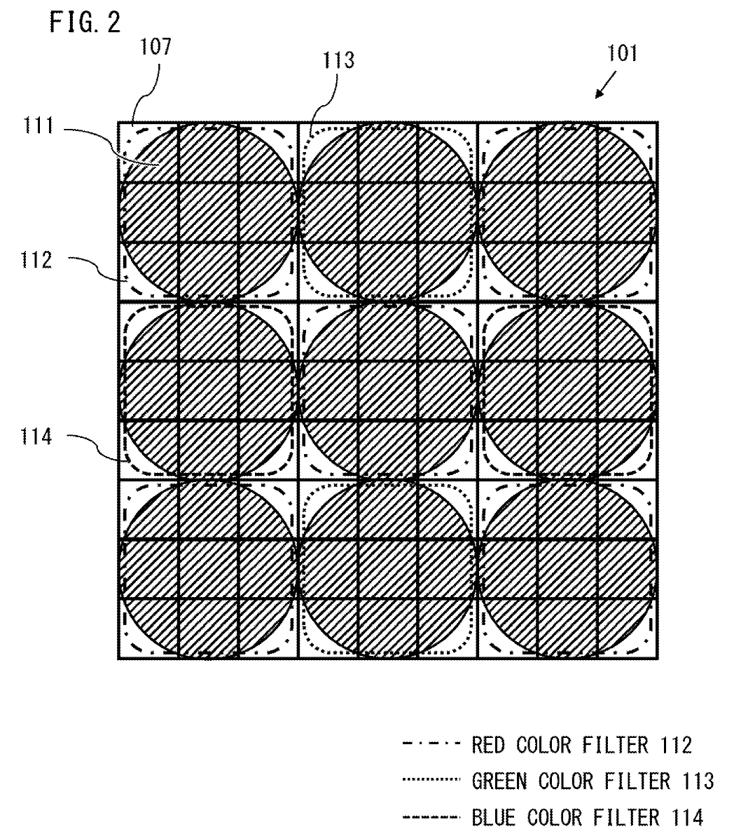

FIG. 2 shows an example of the arrangement of the pixels 107 in the pixel array 101 in a plan view of the semiconductor substrate 110 in the imaging device 1. As shown in FIG. 2, color filters are arranged on the pixels 107. FIG. 2 also schematically shows an example in which red, green, and blue color filters are arranged in a Bayer array for pixels of three rows and three columns. In FIG. 2, a red color filter 112 is indicated by a dot-dash line, a green color filter 113 is indicated by a dotted line, and a blue color filter 114 is indicated by a broken line.

Also, as shown in FIG. 2, a microlens 111 is disposed to direct light onto the plurality of pixels 107. In the present embodiment, the plurality of microlenses 111 are arranged such that each of the microlenses 111 corresponds to the plurality of pixels arranged in three rows and three columns. Since the plurality of pixels 107 are arranged for the single microlens 111, phase difference information can be obtained by a combination of the microlens 111 and the pixels 107. In the imaging device 1, a so-called image plane phase difference auto-focus can be achieved using the acquired phase difference information.

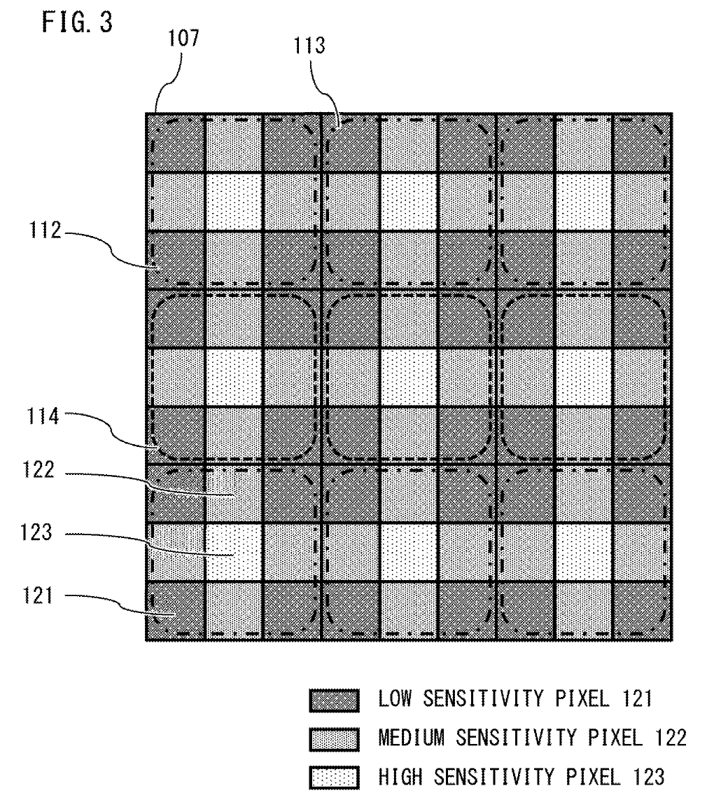

FIG. 3 schematically shows the planar structure of the pixels and the sensitivity of the pixels with respect to the arrangement of the pixels and the microlenses illustrated in FIG. 2. In FIG. 3, the sensitivity of the pixels through the microlens is shown as a pattern for the pixels 107 corresponding to the color filter of the same color. FIG. 3 shows that when the pixels are arranged in three rows and three columns, the sensitivities of the pixels through one microlens are three types: high sensitivity, intermediate sensitivity, and low sensitivity. In the present embodiment, it is assumed that the microlens has a spherical shape, and therefore, the pixels arranged in three rows and three columns include a pixel 123 disposed at the center with the highest sensitivity (high-sensitivity pixel). Furthermore, pixels 121 disposed in pairs in a diagonal direction of the substrate 110 have low sensitivity (low-sensitivity pixel). In addition, pixels 122 arranged in the vertical and horizontal directions of the substrate 110 have medium sensitivity (medium-sensitivity pixel). It should be noted that the diagonal direction of the substrate 110 may be the same direction as a diagonal direction of a lattice pattern, which will be described later. The pixels 121 disposed in pairs in a diagonal direction of the substrate 110 may be the pixels 121 disposed on a diagonal line of the lattice pattern.

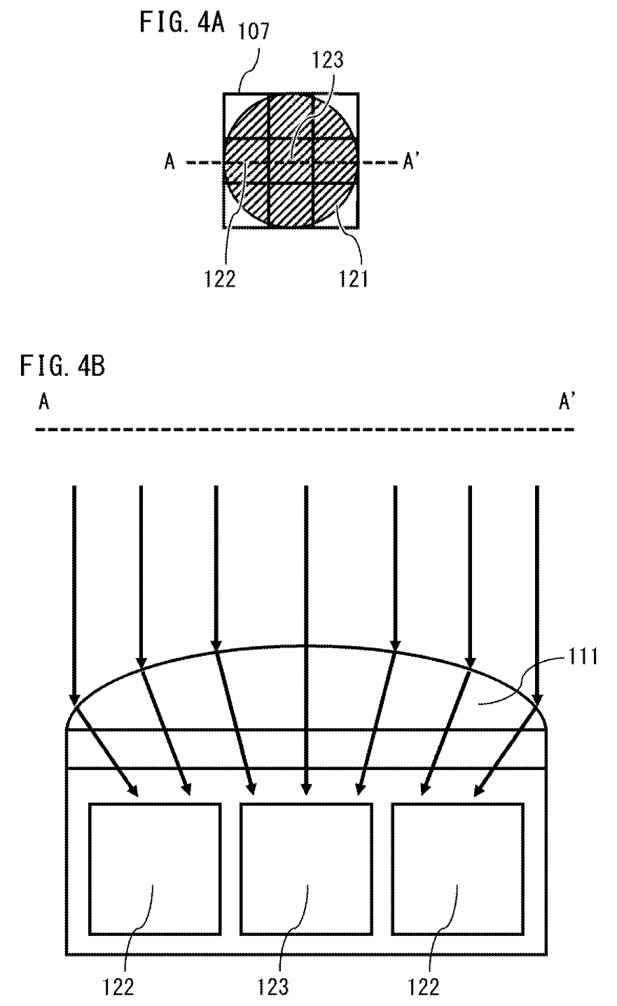

FIG. 4A shows one microlens and the corresponding pixels in the arrangement of the pixels and the microlenses shown in FIG. 2. FIG. 4B schematically shows a cross section along line A-A' extending in the lateral direction of the substrate 110 in FIG. 4A, and incident light condensed through the microlens 111. As shown in FIG. 4B, the high-sensitivity pixel 123 disposed at the center receives a larger amount of light than the medium-sensitivity pixels 122 disposed on the right side and left side of the substrate 110.

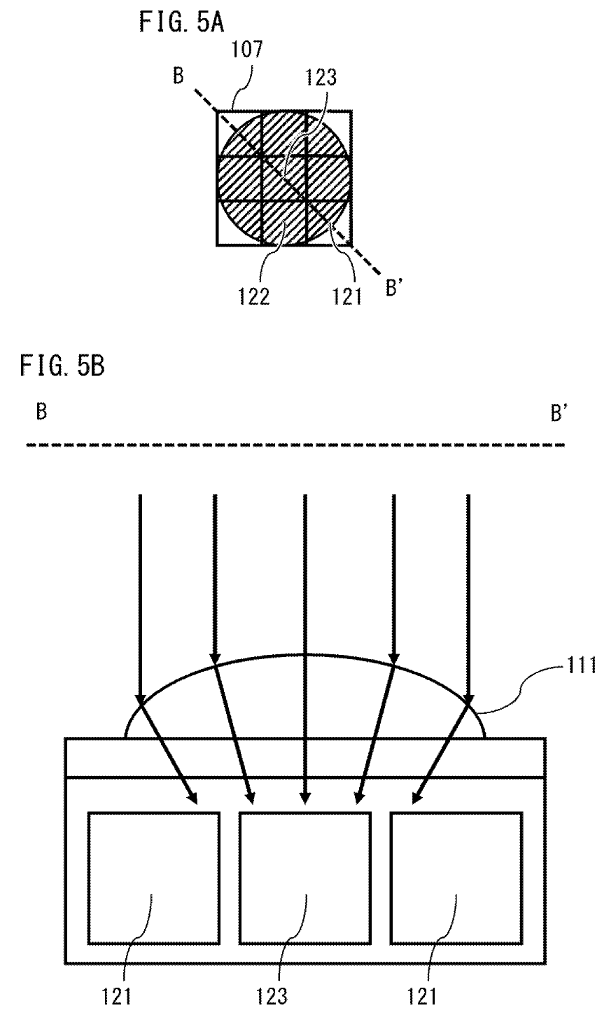

FIG. 5A shows one microlens and the corresponding pixels as in FIG. 4A. FIG. 5B schematically shows a cross section along line B-B' extending in a diagonal direction of the substrate 110 in FIG. 5A, and incident light condensed through the microlens 111. As shown in FIG. 5B, a larger amount of incident light condensed through the microlens 111 enters the high-sensitivity pixel 123. Moreover, in the low-sensitivity pixel 121, the amount of incident light condensed through the microlens 111 is smaller than the amount of light incident on the high-sensitivity pixel 123. As described above, in the configuration in which the single microlens 111 is disposed for the plurality of pixels 107, a difference in sensitivity occurs between the pixels 107.

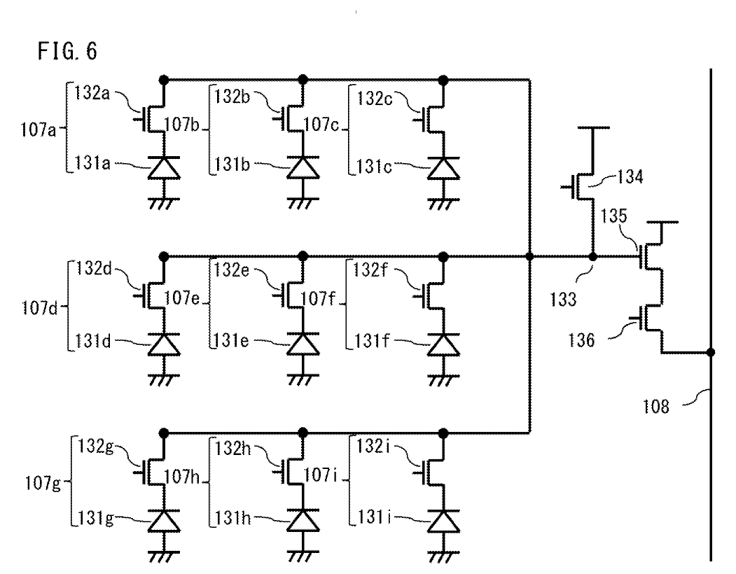

FIG. 6 shows an example of an equivalent circuit of the pixels in the pixel array including a combination of the pixels 107 in three rows and three columns and the single microlens 111 shown in FIG. 2. As shown in FIG. 6, a pixel 107a includes a photodiode 131a and a transfer transistor 132a as an example of a photoelectric conversion element. Similarly, pixels 107b to 107i also include photodiodes 131b to 131i and transfer transistors 132b to 132i, respectively. The pixels 107a to 107i are connected to a floating diffusion 133, and the floating diffusion 133 is connected to a reset transistor 134 and an amplification transistor 135. The amplification transistor 135 is connected to a selection transistor 136. In the present embodiment, the vertical scanning circuit 102 shown in FIG. 1 inputs, to the transistors, the control signal for controlling the gates of the transistors. The photodiodes 131a to 131i photoelectrically convert light entering the pixels 107a to 107i from the microlens 111, and accumulate signal charge generated by the photoelectric conversion.

The transfer transistors 132a to 132i are controlled by the control signal input to the gates. When the transistors are turned on, the charges of the sets of the photodiodes 131a to 131i are transferred to the floating diffusion 133. The drain of the amplification transistor 135 is connected to a power supply voltage line VDD, and the source thereof is connected to the drain of the selection transistor 136. The source of the selection transistor 136 is connected to the column signal line 108. A constant current source (not shown) is connected to the column signal line 108.

The selection transistor 136 is controlled by the control signal input to the gate and is turned on to connect the source of the amplification transistor 135 to the column signal line 108, thereby functioning as a source follower. At this time, an output signal Vout based on the voltage of the floating diffusion 133 is output to the column amplifier circuit 103 shown in FIG. 1 through the column signal line 108 of each column. In this configuration, it is assumed that the floating diffusion 133 is shared among the plurality of pixels 107a to 107i that share the single microlens 111. The pixel array configured thus enables a binning operation in which signals are summed and read among the plurality of pixels 107a to 107i sharing the floating diffusion 133, and thus it is expected to increase the reading speed of each pixel and improve the SN ratio.

In contrast, a configuration may be adopted such that the floating diffusion 133 is not shared among the plurality of pixels but is disposed for each of the photodiodes 131a to 131i in the example of FIG. 6. In such a configuration, a binning operation cannot be performed such that signal charges in the respective floating diffusions 133 are summed and read. However, since the capacity of the floating diffusion 133 assigned to each pixel can be reduced, random noise in each pixel can be suppressed.

The following example will describe a pixel configuration for implementing phase difference detection in a combination of the plurality of pixels 107, which constitute the pixel array 101, and one microlens according to the present embodiment.

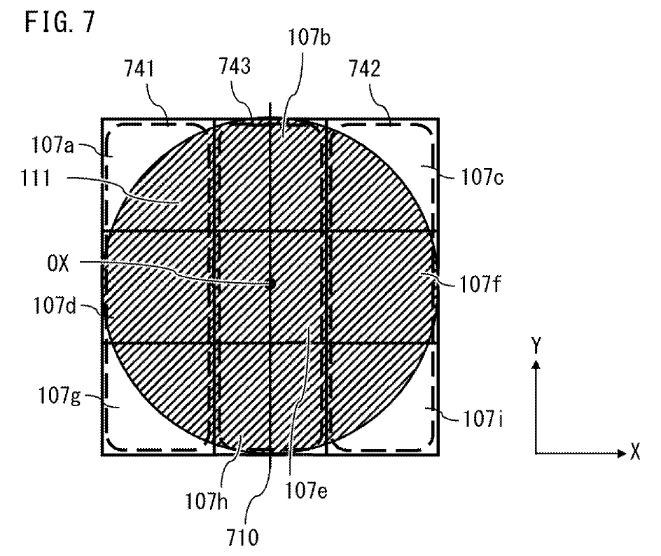

FIG. 7 shows a configuration example for detecting a phase difference in the lateral direction of the substrate 110 in a configuration in which the plurality of pixels 107a to 107i in three rows and three columns and the microlens 111 shared by the plurality of pixels 107a to 107i are arranged as a set. As shown in FIG. 7, the X-axis is set to extend in the lateral direction of the substrate 110, and the Y-axis is set to extend in the vertical direction of the substrate 110 orthogonal to the X-axis. Furthermore, the X-axis direction is the row direction in which the pixels 107 are arranged, and the Y-axis direction is the column direction in which the pixels 107a to 107i are arranged. In order to detect a phase difference in the pixel configuration shown in FIG. 7, light having passed through a region on the right side of the microlens 111 (the right side of the substrate 110 and the positive side of the X-axis) and light having passed through a region on the left side of the microlens 111 (the left side of the substrate 110 and the negative side of the X-axis) are directed onto the pixels. FIG. 7 also shows an optical axis OX of the microlens 111. The optical axis OX extends in a direction perpendicular to the XY plane.

As shown in FIG. 7, the plurality of pixels 107a to 107i are arranged in a lattice pattern on the substrate 110. In the example shown in FIG. 7, the plurality of pixels 107a to 107i are arranged in three rows and three columns. In addition, among the plurality of pixels 107a to 107i arranged in three rows and three columns, a pixel group 741 for left phase difference detection is provided with the three pixels 107a, 107d, and 107g arranged in the column direction on the left side of the substrate 110. Moreover, among the plurality of pixels 107a to 107i arranged in three rows and three columns, a pixel group 742 for left phase difference detection is provided with the three pixels 107c, 107f, and 107i arranged in the column direction on the right side of the substrate 110. In the present embodiment, the pixel groups 741 and 742 are arranged with point symmetry with respect to the optical axis OX of the microlens 111 in a plan view of the substrate 110. Furthermore, the pixel groups 741 and 742 are arranged with point symmetry with respect to a straight line 710 passing through the optical axis OX of the microlens 111 in the plan view of the substrate 110.

As shown in FIG. 7, the pixel group 741 for left phase difference detection includes the pixel 107d having a medium sensitivity and the pixels 107a and 107g having a low sensitivity, and the pixel group 742 for right phase difference detection includes the pixel 107f having a medium sensitivity and the pixels 107c and 107i having a low sensitivity. Here, as an example, the pixels 107d and 107f having a medium sensitivity are pixels having a first sensitivity, whereas the pixels 107a, 107c, 107g and 107i having the low sensitivity are pixels having a second sensitivity.

In the present embodiment, phase difference detection in the lateral direction of the substrate 110 is implemented by the pixel groups 741 and 742. FIG. 7 shows an example in which the pixel group 741 for left phase difference detection and the pixel group 742 for right phase difference detection are arranged in the column direction of the substrate 110. However, in the present embodiment, a pixel group 743 may also be adopted as a pixel for phase difference detection, the pixel group 743 including the three pixels 107b, 107e, and 107h arranged at the center in the column direction among the plurality of pixels 107a to 107i arranged in three rows and three columns. In this case, the pixel group 743 disposed at the center is used as a pixel group for right phase difference detection or a pixel group for left phase difference detection. Here, as an example, the pixels 107b and 107h having a medium sensitivity are pixels having the first sensitivity, whereas the pixel 107e having a high sensitivity is a pixel having a third sensitivity.

The imaging device 1 according to the present embodiment can acquire phase difference information over a wider illuminance range as compared with a conventional imaging device.

### First Modified Example

Next, a first modified example of the imaging device 1 according to the present embodiment will be described below. In the following description, the same configurations as those of the imaging device 1 will be given the same reference numerals, and a detailed description thereof is omitted.

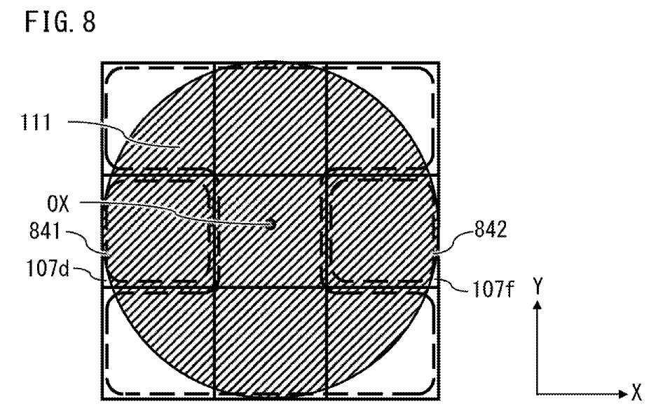

FIG. 8 shows a configuration example for detecting a phase difference in the lateral direction of the substrate 110 in a configuration in which the microlens 111 is shared by the plurality of pixels 107a to 107i in three rows and three columns of the imaging device 1. Referring to FIG. 8, differences between the configurations of the pixels 107a to 107i and the microlens 111 in FIG. 8 and the configurations of the pixels 107a to 107i and the microlens 111 in FIG. 7 will be described below. In the imaging device 1 of the present modified example, a pixel group 841 for left phase difference detection and a pixel group 842 for right phase difference detection, which constitute a pixel pair for phase difference detection, are only the central pixels among the pixels arranged in the column direction on the left and right sides of the substrate 110. Thus, the pixel group 841 includes the pixel 107d, and the pixel group 842 includes the pixel 107f. Furthermore, in the present modified example, the pixel groups 841 and 842 are arranged with point symmetry with respect to the optical axis OX of the microlens 111 in a plan view of the substrate 110.

In the imaging device 1, the maximum illuminance at which a phase difference can be detected is determined by the saturation signal quantity accumulable by the pixels for phase difference detection. Since the pixels of the pixel groups 841 and 842 are only the central pixels among the pixels arranged on the left and right sides of the substrate 110 in the column direction, the sensitivity to incident light from the microlens 111 decreases as compared with the configuration of the pixel groups 741 and 742 (FIG. 7) of the above-described embodiment. Thus, the imaging device 1 of the present modified example achieves a pixel configuration capable of detecting a phase difference to higher illuminance. Therefore, according to the pixel groups 841 and 842 of the present modified example, the sensitivity of the pixel for phase difference detection is lower than in the configuration of the pixel groups 741 and 742 of the above-described embodiment, so that a phase difference can be detected in a higher-illuminance environment even under the same imaging conditions.

### Second Modified Example

A second modified example of the imaging device 1 according to the present embodiment will be described below. In the following description, the same configurations as those of the imaging device 1 will be given the same reference numerals, and a detailed description thereof is omitted.

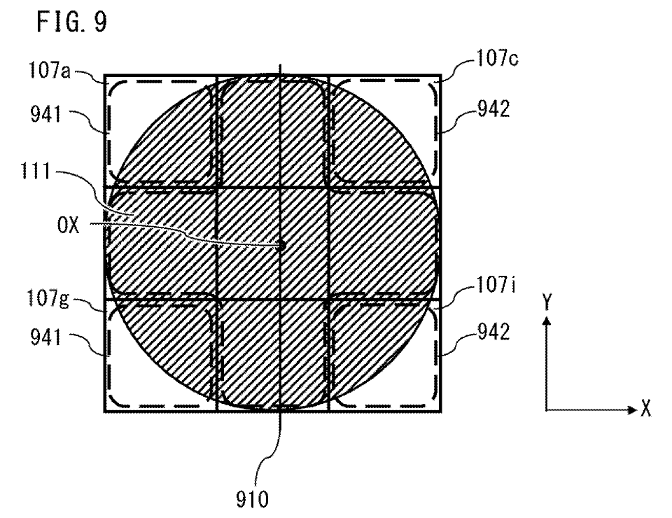

FIG. 9 shows a configuration example for detecting a phase difference in the lateral direction of the substrate 110 in a configuration in which the microlens 111 is shared by the plurality of pixels 107a to 107i in three rows and three columns of the imaging device 1. Referring to FIG. 9, differences between the configurations of the pixels 107a to 107i and the microlens 111 in FIG. 9 and the configurations of the pixels 107a to 107i and the microlens 111 in FIGS. 7 and 8 will be described below. In the imaging device 1 of the present modified example, a pixel group 941 for left phase difference detection and a pixel group 942 for right phase difference detection, which constitute a pixel pair for phase difference detection, include pixels disposed diagonally at portions having the lowest sensitivity among the pixels arranged in three rows and three columns. Accordingly, the pixel group 941 includes the pixels 107a and 107g, and the pixel group 842 includes the pixels 107c and 107i. Furthermore, in the present modified example, the pixel groups 941 and 942 are arranged with point symmetry with respect to the optical axis OX of the microlens 111 in a plan view of the substrate 110. In addition, the pixel groups 941 and 942 are arranged with line symmetry with respect to a straight line 910 passing through the optical axis OX of the microlens 111 in the plan view of the substrate 110.

Therefore, according to the pixel groups 941 and 942 of the present modified example, the pixels having low sensitivity to incident light from the microlens 111 are used for phase difference detection. Thus, as in the first modified example, the sensitivity of the pixel for phase difference detection is lower than in the configuration of the pixel groups 741 and 742 of the above-described embodiment, so that a phase difference can be detected in a higher-illuminance environment even under the same imaging conditions.

### Third Modified Example

A third modified example of the imaging device 1 according to the present embodiment will be described below. In the following description, the same configurations as those of the imaging device 1 will be given the same reference numerals, and a detailed description thereof is omitted.

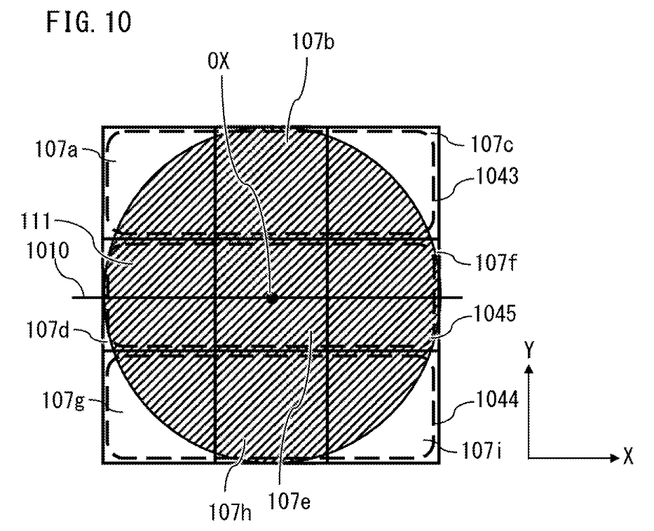

FIG. 10 shows a configuration example for detecting a phase difference in the vertical direction of the substrate 110 in a configuration in which the microlens 111 is shared by the plurality of pixels 107a to 107i in three rows and three columns of the imaging device 1. The pixels 107a to 107i shown in FIGS. 7 to 9 are configured for detecting a phase difference in the lateral direction of the substrate 110. In such a configuration, high-precision autofocus can be performed on a subject having a stripe pattern in the vertical direction of the substrate 110. In contrast, in the configurations of the pixels 107a to 107i shown in FIGS. 7 to 9, the accuracy of autofocus on a subject having a stripe pattern in the lateral direction is lower than that of autofocus on a subject having a stripe pattern in the vertical direction.

In FIG. 10, among the plurality of pixels 107a to 107i arranged in three rows and three columns, a pixel group 1043 for upper phase difference detection is provided with the three pixels 107a, 107b, and 107c arranged in the row direction on the upper side of the substrate 110. In addition, among the plurality of pixels 107a to 107i arranged in three rows and three columns, a pixel group 1044 for lower phase difference detection is provided with the three pixels 107g, 107h, and 107i arranged in the row direction on the lower side of the substrate 110. The phase difference detection in the vertical direction of the substrate 110 is implemented by the pixel groups 1043 and 1044.

In the present modified example, the pixel groups 1043 and 1044 are arranged with point symmetry with respect to the optical axis OX of the microlens 111 in a plan view of the substrate 110. In addition, the pixel groups 1043 and 1044 are arranged with line symmetry with respect to a straight line 1010 passing through the optical axis OX of the microlens 111 in the plan view of the substrate 110.

FIG. 10 shows an example in which the pixel group 1043 for upper phase difference detection and the pixel group 1044 for lower phase difference detection are arranged in the row direction of the substrate 110. However, in the present modified example, a pixel group 1045 may also be adopted as a pixel for phase difference detection, the pixel group 1045 including the three pixels 107d, 107e, and 107f arranged at the center in the row direction among the plurality of pixels 107a to 107i arranged in three rows and three columns. In this case, the pixel group 1045 disposed at the center is used as a pixel group for upper phase difference detection or a pixel group for lower phase difference detection.

### Fourth Modified Example

A fourth modified example of the imaging device 1 according to the present embodiment will be described below. In the following description, the same configurations as those of the imaging device 1 will be given the same reference numerals, and a detailed description thereof is omitted.

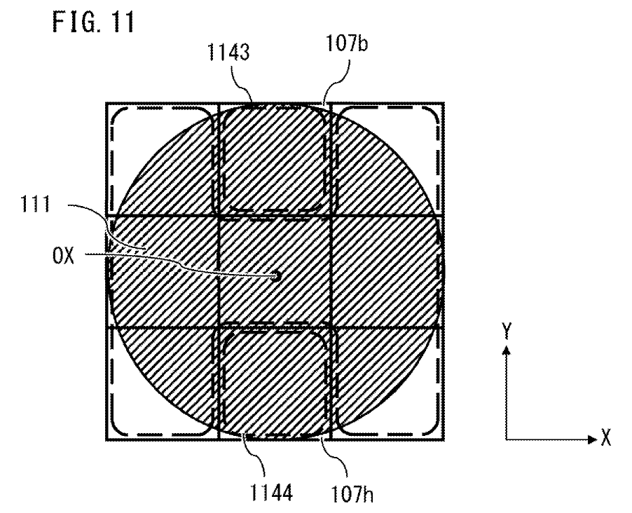

FIG. 11 shows a configuration example for detecting a phase difference in the vertical direction of the substrate 110 in a configuration in which the microlens 111 is shared by the plurality of pixels 107a to 107i in three rows and three columns of the imaging device 1. Referring to FIG. 11, differences between the configurations of the pixels 107a to 107i and the microlens 111 in FIG. 11 and the configurations of the pixels 107a to 107i and the microlens 111 in FIG. 10 will be described below. In the imaging device 1 of the present modified example, a pixel group 1143 for upper phase difference detection and a pixel group 1144 for lower phase difference detection, which constitute a pixel pair for phase difference detection, are only the central pixels among the pixels arranged in the row direction on the upper and lower sides of the substrate 110. Accordingly, the pixel group 1143 includes the pixel 107b, and the pixel group 1144 includes the pixel 107h. Furthermore, in the present modified example, the pixel groups 1143 and 1144 are arranged with point symmetry with respect to the optical axis OX of the microlens 111 in a plan view of the substrate 110.

According to the imaging device 1 of the present modified example, the pixel group 1143 for upper phase difference detection and the pixel group 1144 for lower phase difference detection are the pixels 107b and 107h disposed at the center of the upper and lower sides of the substrate 110 among the pixels 107a to 107i arranged in three rows and three columns. Therefore, according to the pixel groups 1143 and 1144 of the present modified example, the sensitivity of the pixel for phase difference detection is lower than in the configuration of the pixel groups 1043 and 1044 (FIG. 10) of the third modified example, so that a phase difference can be detected in a higher-illuminance environment even under the same imaging conditions.

### Fifth Modified Example

A fifth modified example of the imaging device 1 according to the present embodiment will be described below. In the following description, the same configurations as those of the imaging device 1 will be given the same reference numerals, and a detailed description thereof is omitted.

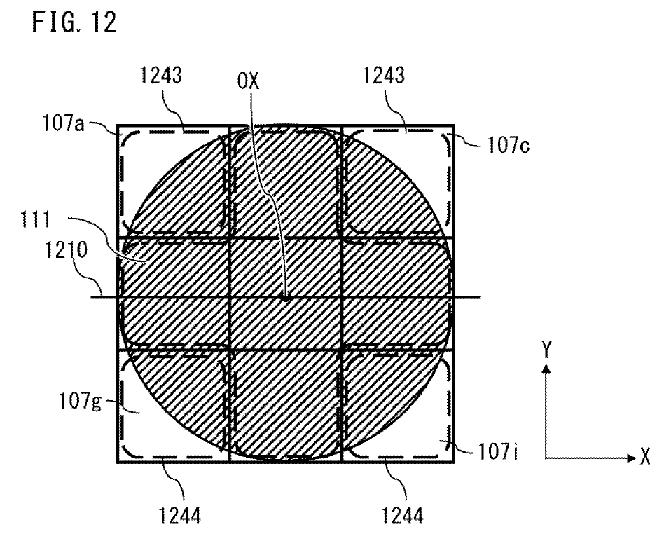

FIG. 12 shows a configuration example for detecting a phase difference in the vertical direction of the substrate 110 in a configuration in which the microlens 111 is shared by the plurality of pixels 107a to 107i in three rows and three columns of the imaging device 1. Referring to FIG. 12, differences between the configurations of the pixels 107a to 107i and the microlens 111 in FIG. 12 and the configurations of the pixels 107a to 107i and the microlens 111 in FIGS. 10 and 11 will be described below. In the imaging device 1 of the present modified example, a pixel group 1243 for upper phase difference detection and a pixel group 1244 for lower phase difference detection, which constitute a pixel pair for phase difference detection, include pixels disposed diagonally at portions having the lowest sensitivity among the pixels arranged in three rows and three columns. Accordingly, the pixel group 1243 includes the pixels 107a and 107c, and the pixel group 1244 includes the pixels 107g and 107i. Furthermore, in the present modified example, the pixel groups 1243 and 1244 are arranged with point symmetry with respect to the optical axis OX of the microlens 111 in a plan view of the substrate 110. In addition, the pixel groups 1243 and 1244 are arranged with line symmetry with respect to a straight line 1210 passing through the optical axis OX of the microlens 111 in the plan view of the substrate 110.

Therefore, according to the pixel groups 1243 and 1244 of the present modified example, the pixels having low sensitivity to incident light from the microlens 111 are used for phase difference detection. Thus, as in the fourth modified example, the sensitivity of the pixel for phase difference detection is lower than in the configuration of the pixel groups 1043 and 1044 of the third modified example, so that a phase difference can be detected in a higher-illuminance environment even under the same imaging conditions.

### Sixth Modified Example

A sixth modified example of the imaging device 1 according to the present embodiment will be described below. In the following description, the same configurations as those of the imaging device 1 will be given the same reference numerals, and a detailed description thereof is omitted.

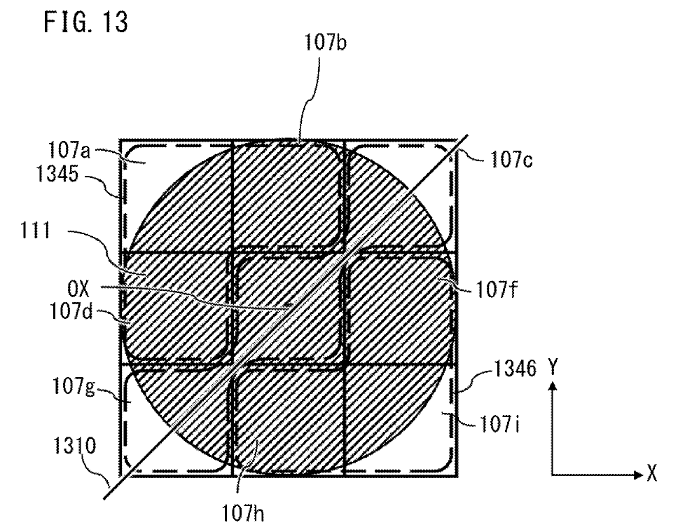

FIG. 13 shows a configuration example for detecting a phase difference in a diagonal direction of the substrate 110 (a direction not parallel to the X-axis and the Y-axis on the substrate) in a configuration in which the microlens 111 is shared by the plurality of pixels 107a to 107i in three rows and three columns of the imaging device 1. The pixels 107a to 107i shown in FIGS. 7 to 12 are configured for detecting a phase difference in the lateral direction or the vertical direction of the substrate 110. In such a configuration, high-precision autofocus can be performed on a subject having a stripe pattern in the vertical direction or the lateral direction of the substrate 110. In contrast, in the configurations of the pixels 107a to 107i shown in FIGS. 7 to 12, the accuracy of autofocus on a subject having a stripe pattern in the vertical direction or the lateral direction is lower than that of autofocus on a subject having a stripe pattern in a diagonal direction of the substrate 110.

In FIG. 13, among the plurality of pixels 107a to 107i arranged in three rows and three columns, a pixel group 1345 for upper-left phase difference detection is provided with the three pixels 107a, 107b, and 107d arranged in the upper left region of the substrate 110. In addition, among the plurality of pixels 107a to 107i arranged in three rows and three columns, a pixel group 1346 for lower-right phase difference detection is provided with the three pixels 107f, 107h, and 107i arranged in the lower right region of the substrate 110. Furthermore, in the present modified example, the pixel groups 1345 and 1346 are arranged with point symmetry with respect to the optical axis OX of the microlens 111 in a plan view of the substrate 110. In addition, the pixel groups 1345 and 1346 are arranged with line symmetry with respect to a straight line 1310 passing through the optical axis OX of the microlens 111 in the plan view of the substrate 110.

The phase difference detection in the diagonal direction of the substrate 110 is implemented by the pixel groups 1345 and 1346. In particular, in the imaging device 1 according to the present modified example, autofocus on a subject having a stripe pattern in the diagonal direction from the upper right to the lower left of the substrate 110 can be performed with higher accuracy than autofocus on a subject having another stripe pattern.

FIG. 13 shows an example of the pixel groups 1345 and 1346 in which the three pixels 107a, 107b, and 107d arranged in the upper left region and the three pixels 107f, 107h, and 107i arranged in the lower right region are paired on the substrate 110. However, the pixels constituting the pixel groups 1345 and 1346 are not limited to the above example. For example, the pixel group 1345 may include the three pixels 107b, 107c, and 107f arranged in the upper right region of the substrate 110, and the pixel group 1346 may include the three pixels 107d, 107g, and 107h arranged in the lower left region of the substrate 110. In this case, autofocus on a subject having a stripe pattern in a diagonal direction from the upper left to the lower left of the substrate 110 can be performed with higher accuracy than autofocus on a subject having another stripe pattern.

### Seventh Modified Example

A seventh modified example of the imaging device 1 according to the present embodiment will be described below. In the following description, the same configurations as those of the imaging device 1 will be given the same reference numerals, and a detailed description thereof is omitted.

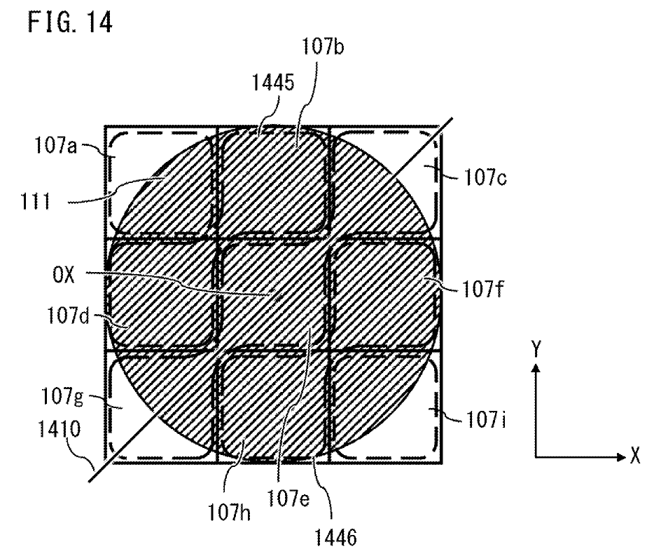

FIG. 14 shows a configuration example for detecting a phase difference in a diagonal direction of the substrate 110 in a configuration in which the microlens 111 is shared by the plurality of pixels 107a to 107i in three rows and three columns of the imaging device 1. Referring to FIG. 14, differences between the configurations of the pixels 107a to 107i and the microlens 111 in FIG. 14 and the configurations of the pixels 107a to 107i and the microlens 111 in FIG. 13 will be described below. In the imaging device 1 of the present modified example, a pixel group 1445 for upper-left phase difference detection and a pixel group 1446 for lower-right phase difference detection, which are provided for phase difference detection, include pixels other than the pixels 107a, 107c, 107g, and 107i located on the four corners and the central pixel 107e. Therefore, the pixel group 1445 for upper-left phase difference detection and the pixel group 1446 for lower-right phase difference detection include the pixels 107b, 107d, 107f, 107h on the opposite sides. Furthermore, in the present modified example, the pixel groups 1445 and 1446 are arranged with point symmetry with respect to the optical axis OX of the microlens 111 in a plan view of the substrate 110. In addition, the pixel groups 1445 and 1446 are arranged with line symmetry with respect to a straight line 1410 passing through the optical axis OX of the microlens 111 in the plan view of the substrate 110.

The phase difference detection in the diagonal direction of the substrate 110 is implemented by the pixel groups 1445 and 1446. In particular, in the imaging device 1 according to the present modified example, autofocus on a subject having a stripe pattern in the diagonal direction from the upper right to the lower left of the substrate 110 can be performed with higher accuracy than autofocus on a subject having another stripe pattern.

In the imaging device 1 of the present modified example, the pixel group 1445 for upper-left phase difference detection and the pixel group 1446 for lower-right phase difference detection include the pixels 107b, 107d, 107f, and 107h on the opposite sides from among the pixels 107a to 107i in three rows and three columns. The pixel groups 1445 and 1446 only include the central pixel from among the pixels arranged on the upper, lower, left, and right sides of the substrate 110 in the column direction. Thus, the sensitivity to incident light from the microlenses 111 is lower than that in the configuration of the pixel groups 1345 and 1346 (FIG. 13) of the sixth modified example. Thus, the imaging device 1 of the present modified example achieves a pixel configuration capable of detecting a phase difference to higher illuminance. Therefore, according to the pixel groups 1445 and 1446 of the present modified example, the sensitivity of the pixel for phase difference detection is lower than in the configuration of the pixel groups 1345 and 1346 of the sixth modified example, so that a phase difference can be detected in a higher-illuminance environment even under the same imaging conditions.

FIG. 14 shows an example of the pixel groups 1445 and 1446 in which the two pixels 107b and 107d on the upper left side and the two pixels 107f and 107h on the lower right side are paired on the substrate 110. However, the pixels constituting the pixel groups 1445 and 1446 are not limited to the above example. For example, the pixel group 1445 may include the two pixels 107b and 107f arranged on the upper right side of the substrate 110, and the pixel group 1446 may include the two pixels 107d and 107h arranged on the lower left side of the substrate 110. In this case, autofocus on a subject having a stripe pattern in a diagonal direction from the upper left to the lower left of the substrate 110 can be performed with higher accuracy than autofocus on a subject having another stripe pattern.

### Eighth Modified Example

An eighth modified example of the imaging device 1 according to the present embodiment will be described below. In the following description, the same configurations as those of the imaging device 1 will be given the same reference numerals, and a detailed description thereof is omitted.

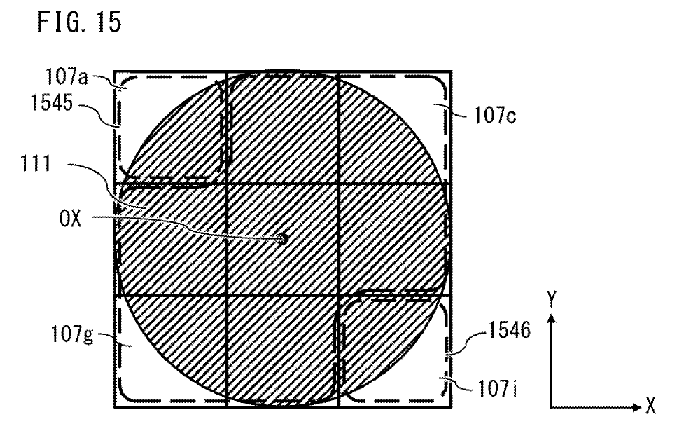

FIG. 15 shows a configuration example for detecting a phase difference in a diagonal direction of the substrate 110 in a configuration in which the microlens 111 is shared by the plurality of pixels 107a to 107i in three rows and three columns of the imaging device 1. Referring to FIG. 15, differences between the configurations of the pixels 107a to 107i and the microlens 111 in FIG. 15 and the configurations of the pixels 107a to 107i and the microlens 111 in FIGS. 13 and 14 will be described below. In the imaging device 1 of the present modified example, a pixel group 1545 for upper left phase difference detection and a pixel group 1546 for lower right phase difference detection include pixels disposed diagonally at portions having the lowest sensitivity among the pixels arranged in three rows and three columns. Thus, the pixel group 1545 includes the pixel 107a, and the pixel group 1546 includes the pixel 107i. Furthermore, in the present modified example, the pixel groups 1545 and 1546 are arranged with point symmetry with respect to the optical axis OX of the microlens 111 in a plan view of the substrate 110.

Therefore, according to the pixel groups 1545 and 1546 of the present modified example, the pixels having low sensitivity to incident light from the microlens 111 are used for phase difference detection. Thus, as in the seventh modified example, the sensitivity of the pixel for phase difference detection is lower than in the configuration of the pixel groups 1345 and 1346 of the sixth modified example, so that a phase difference can be detected in a higher-illuminance environment even under the same imaging conditions.

FIG. 15 shows an example of the pixel groups 1545 and 1546 in which the pixel 107a at the upper left corner and the pixels 107i at the lower right corner are paired on the substrate 110. However, the pixels constituting the pixel groups 1545 and 1546 are not limited to the above example. For example, the pixel group 1545 may include the pixel 107c disposed at the upper right corner of the substrate 110, and the pixel group 1546 may include the pixel 107g disposed at the lower left corner of the substrate 110. In this case, autofocus on a subject having a stripe pattern in a diagonal direction from the upper left to the lower left of the substrate 110 can be performed with higher accuracy than autofocus on a subject having another stripe pattern.

### Second Embodiment

An imaging device 1 according to a second embodiment will be described below. In the following description, the same configurations as those of the imaging device 1 will be given the same reference numerals, and a detailed description thereof is omitted.

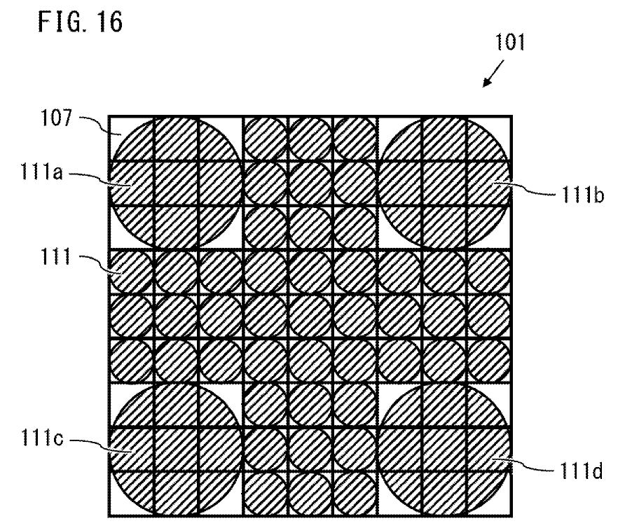

FIG. 16 shows a configuration example of a plurality of pixels 107 and microlenses 111 in a pixel array 101 of the imaging device 1 according to the present embodiment. In the present embodiment, as shown in FIG. 16, in the arrangement of the microlenses 111 in the pixel array 101, microlenses 111a, 111b, 111c, and 111d shared by the plurality of pixels 107 in three rows and three columns are discretely arranged on a substrate 110. In the pixel array 101, the microlenses 111 other than the microlenses 111a, 111b, 111c, and 111d are arranged such that one microlens corresponds to one of the pixels 107.

If a phase difference is detected for all the pixels of the pixel array 101 in the imaging device 1, the accuracy of the phase difference detection is improved, but the magnitude of the processing load is not negligible. In contrast, in the imaging device 1 according to the present embodiment, only the pixels sharing the microlenses 111a, 111b, 111c, and 111d are used as a pixel group for phase difference detection. As the configurations of the microlenses 111a, 111b, 111c, and 111d and the plurality of pixels 107, the configurations of the first embodiment and modified examples 1 to 8 may be adopted as appropriate. Furthermore, the configurations of the microlenses 111a, 111b, 111c, and 111d and the plurality of pixels 107 may be identical to one another or different from one another.

In the imaging device 1 according to the present embodiment, the pixels 107 not subjected to phase difference detection, that is, the pixels 107 that do not share the microlenses 111a to 111d do not share the microlenses 111 with the other pixels 107. Accordingly, the pixel array 101 shown in FIG. 16 is configured such that the pixels 107 sharing the microlenses 111a to 111d are discretely disposed and the microlenses 111 are arranged in a one-to-one correspondence with the other pixels 107.

According to the imaging device 1 of the present embodiment, like the imaging devices 1 of the first embodiment and the modified examples, phase difference information can be obtained over a wider illuminance range than the conventional imaging device. Furthermore, according to the present embodiment, the processing load associated with phase difference detection can be reduced as compared with an imaging device that is not configured with the microlenses 111a to 111d and the plurality of pixels 107, for example, an imaging device in which pixels and microlenses are arranged in a one-to-one correspondence.

### Ninth Modified Example

A ninth modified example of the imaging device 1 according to the present embodiment will be described below. In the following description, the same configurations as those of the imaging device 1 will be given the same reference numerals, and a detailed description thereof is omitted.

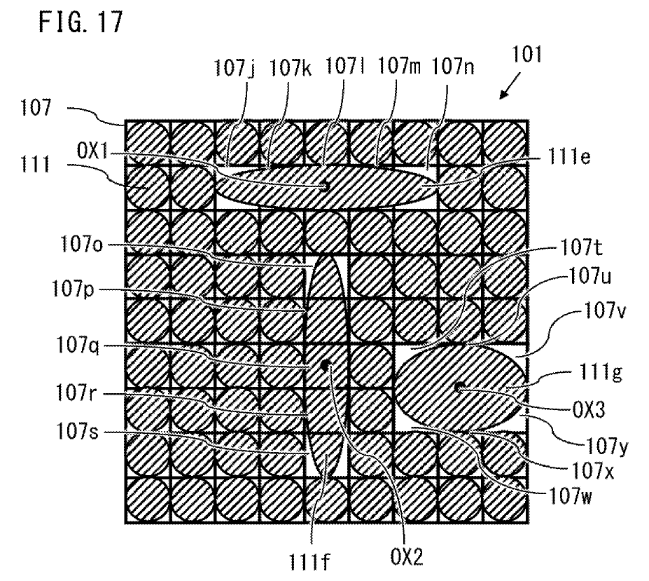

FIG. 17 shows a configuration example of the pixels 107 and the microlenses 111 in the pixel array 101 of the imaging device 1 according to the present modified example. As shown in FIG. 17, in the pixel array 101, pixels 107j, 107k, 107l, 107m, and 107n in one row and five columns are arranged to share one microlens 111e. Furthermore, pixels 107o, 107p, 107q, 107r, and 107s in five rows and one column are arranged to share one microlens 111f. The pixels 107t, 107u, 107v, 107w, 107x, and 107y in two rows and three columns are arranged to share one microlens 111g. FIG. 17 shows optical axes OX1, OX2 and OX3 passing through the lens centers of the microlenses 111e, 111f, and 111g, respectively.

In the example shown in FIG. 17, the pixel sensitivity is uniform in a combination of the pixel 107j and the pixel 107n, a combination of the pixel 107k and the 107m, a combination of the pixel 107o and the pixel 107s, a combination of the pixel 107p and the pixel 107r, and a combination of the pixel 107t, the pixel 107v, the pixel 107w, and the pixel 107y. Furthermore, the pixels 107j to 107n can be classified into three levels of sensitivity such that the pixel 107l is a high-sensitivity pixel, the pixels 107k and 107m are medium-sensitivity pixels, and the pixels 107j and 107n are low-sensitivity pixels. Similarly, the pixels 107o to 107s can be classified into three levels of sensitivity such that the pixel 107q is a high-sensitivity pixel, the pixels 107p and 107r are medium-sensitivity pixels, and the pixels 107o and 107s are low-sensitivity pixels. In addition, the pixels 107t to 107y can be classified into two levels of sensitivity such that the pixel 107u and the pixel 107x are high-sensitivity pixels, and the pixels 107t, the pixel 107v, the pixel 107w, and the pixel 107y are low-sensitivity pixels.

Accordingly, in the imaging device 1, in each of the combination of the pixel 107j and the pixel 107n and the combination of the pixel 107k and the pixel 107m, the pixels are arranged with point symmetry with respect to the optical axis OX1 of the microlens 111e in the lateral direction of the substrate 110. In each of the combination of the pixel 107o and the pixel 107s and the combination of the pixel 107p and the pixel 107r, the pixels are arranged with point symmetry with respect to the optical axis OX2 of the microlens 111f in the vertical direction of the substrate 110. Furthermore, in the combination of the pixel 107t, the pixel 107v, and the pixels 107w and 107y, the pixels are arranged with point symmetry with respect to the optical axis OX3 of the microlens 111g.

Therefore, also in the imaging device 1 according to the present modified example, a sensitivity difference occurs between the pixels sharing the microlens 111, and the imaging device 1 according to the present modified example may have the configurations of the microlenses and the plurality of pixels according to the first embodiment and the modified examples. Thus, by using a sensitivity difference between the plurality of pixels sharing the microlenses, the imaging device 1 can extend the illuminance range in which a phase difference can be detected, as compared with the conventional imaging device.

Incidentally, in the above-described embodiment and modified examples, the plurality of pixels sharing the microlens are not limited to the arrangement exemplified by three rows and three columns, and any arrangement may be adopted as long as the pixels are arranged in a lattice pattern of M rows and N columns (M and N are natural numbers, M≠N).

### Third Embodiment

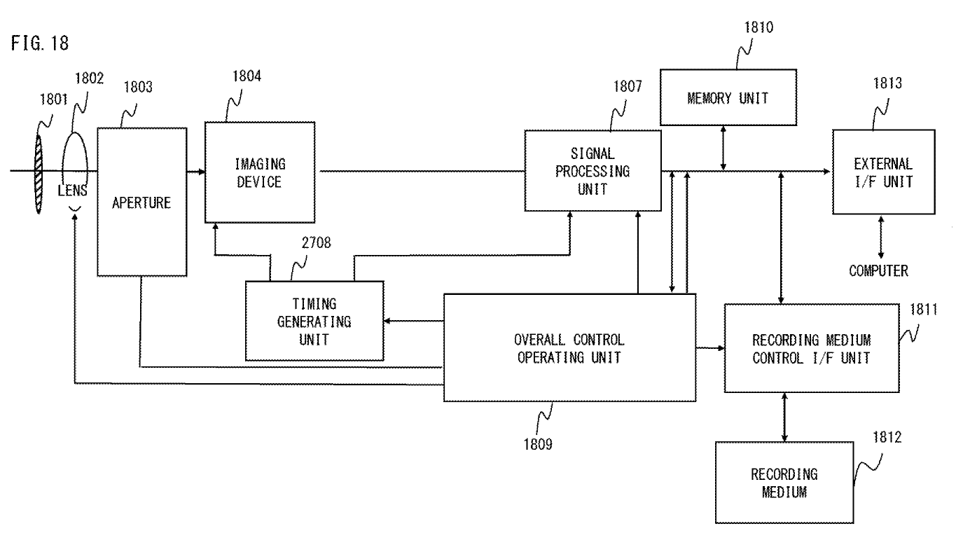

A photoelectric conversion system according to the present embodiment will be described with reference to FIG. 18. FIG. 18 is a block diagram showing a schematic configuration of the photoelectric conversion system according to the present embodiment.

The imaging devices (examples of the photoelectric conversion devices) described in the first and second embodiments can be applied to various photoelectric conversion systems. Each of the photoelectric conversion systems includes at least the photoelectric conversion devices according to any of the embodiments described above and a signal processing unit that processes signals output from the photoelectric conversion device. Examples of devices to which such a photoelectric conversion system can be applied include a digital still camera, a digital camcorder, a monitoring camera, a copier, a facsimile, a mobile phone, a vehicle-mounted camera, an observation satellite, a sensor, and a measuring instrument. In addition, camera modules provided with an optical system such as a lens and an imaging device are also included in devices to which a photoelectric conversion system is applied. FIG. 18 illustrates a block diagram of a digital still camera as an example of such devices.

The photoelectric conversion system illustrated in FIG. 18 has an imaging device 1804 as an example of the photoelectric conversion device and a lens 1802 that causes an optical image of an object to be formed on the imaging device 1804. In addition, the photoelectric conversion system has an aperture 1803 for making a light amount that passes through the lens 1802 variable and a barrier 1801 for protecting the lens 1802. The lens 1802 and the aperture 1803 are optical systems for collecting light to the imaging device 1804. The imaging device 1804 is the photoelectric conversion device (imaging device) according to any of the embodiments described above and converts an optical image having been formed by the lens 1802 into an electric signal.

The photoelectric conversion system also has a signal processing unit 1807 which is an image generating unit for generating an image by processing an output signal that is output from the imaging device 1804. The signal processing unit 1807 performs operations in which the output signal is subjected to various corrections and compression when necessary and image data is output. The signal processing unit 1807 may be formed on a semiconductor substrate provided with the imaging device 1804 or formed on a semiconductor substrate that is separate from the imaging device 1804. In addition, the imaging device 1804 and the signal processing unit 1807 may be formed on a same semiconductor substrate.

The photoelectric conversion system further has a memory unit 1810 for temporarily storing image data and an external interface unit (an external I/F unit) 1813 for communicating with an external computer or the like. Furthermore, the photoelectric conversion system has a recording medium 1812 such as a semiconductor memory for recording or reading imaging data and a recording medium control interface unit (a recording medium control I/F unit) 1811 for performing recording or reading with respect to the recording medium 1812. The recording medium 1812 may be built into the photoelectric conversion system or may be attachable to and detachable from the photoelectric conversion system.

Furthermore, the photoelectric conversion system has an overall control operating unit 1809 that performs various arithmetic operations and controls the entire digital still camera and a timing generating unit 1808 that outputs various timing signals to the imaging device 1804 and the signal processing unit 1807. In this case, the timing signals and the like may be input from outside and the photoelectric conversion system need at least have the imaging device 1804 and the signal processing unit 1807 that processes an output signal that is output from the imaging device 1804.

The imaging device 1804 outputs an imaging signal to the signal processing unit 1807. The signal processing unit 1807 performs predetermined signal processing on the imaging signal output from the imaging device 1804 and outputs image data. The signal processing unit 1807 generates an image using the imaging signal.

As described above, according to the present embodiment, a photoelectric conversion system to which the photoelectric conversion device (imaging device) according to any of the embodiments described above is applied can be realized.

### Fourth Embodiment

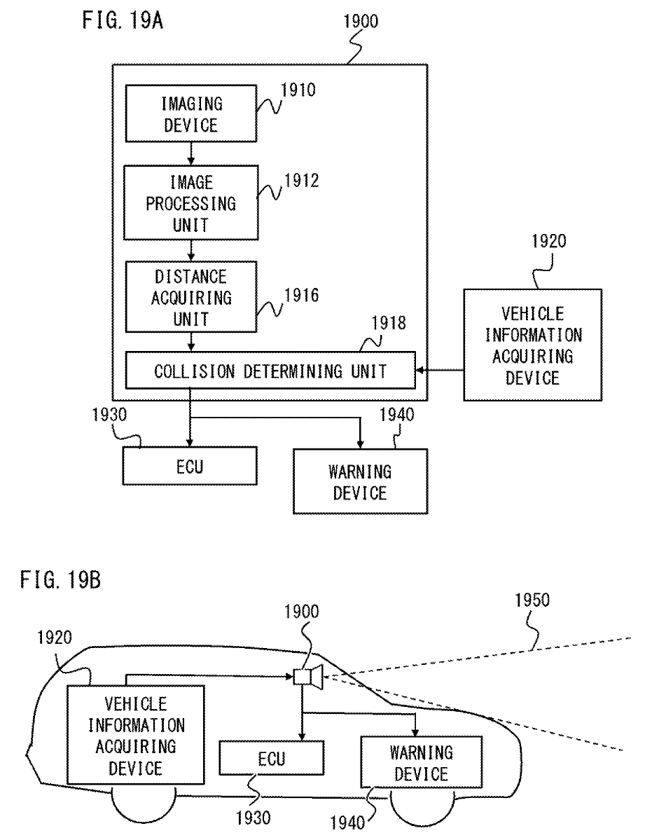

A photoelectric conversion system and a moving body according to the present embodiment will be described with reference to FIGS. 19A and 19B. FIG. 19A is a diagram showing a configuration of the photoelectric conversion system according to the present embodiment and FIG. 19B is a diagram showing a configuration of the moving body according to the present embodiment.

FIG. 19A shows an example of a photoelectric conversion system related to a vehicle-mounted camera. A photoelectric conversion system 1900 includes an imaging device 1910 to which the photoelectric conversion device (imaging device) described in any one of the embodiments described above is applied. The photoelectric conversion system 1900 has an image processing unit 1912 that performs image processing on a plurality of pieces of image data acquired by the imaging device 1910. In addition, the photoelectric conversion system 1900 has a distance acquiring unit 1916 that calculates a distance to an object and a collision determining unit 1918 that determines whether or not there is a possibility of a collision based on the calculated distance. In this case, the distance acquiring unit 1916 may acquire information on the distance to the object based on a ToF (Time of Flight) or may acquire distance information using parallax information or the like. Furthermore, the distance acquiring unit 1916 may acquire distance information by combining ranging according to ToF and ranging based on a phase difference between pixels. In other words, distance information is information related to a parallax, a defocus amount, a distance to the object, or the like. The collision determining unit 1918 may determine a possibility of a collision using any of these pieces of distance information. The distance information acquiring means may be realized by exclusively-designed hardware or may be realized by a software module. Alternatively, the distance information acquiring means may be realized by an FPGA (Field Programmable Gate Array), an ASIC (Application Specific Integrated Circuit), or the like, or a combination thereof.

The photoelectric conversion system 1900 is connected to a vehicle information acquiring device 1920 and is capable of acquiring vehicle information such as a vehicle speed, a yaw rate, and a steering angle. In addition, an ECU 1930 which is a control device that outputs a control signal causing a vehicle to generate a braking force based on a determination result of the collision determining unit 1918 is connected to the photoelectric conversion system 1900. Furthermore, the photoelectric conversion system 1900 is also connected to a warning device 1940 that issues a warning to a driver based on a determination result of the collision determining unit 1918. For example, when it is found that the possibility of a collision is high as a determination result of the collision determining unit 1918, the ECU 1930 performs vehicle control involving applying the brakes, releasing the gas pedal, suppressing engine output, or the like to avoid a collision and/or reduce damage. The warning device 1940 issues a warning to a user by sounding an alarm, displaying warning information on a screen of a car navigation system or the like, vibrating a seat belt or a steering wheel, or the like.

In the present embodiment, an image of a periphery of the vehicle such as the front or the rear of the vehicle is picked up by the photoelectric conversion system 1900. FIG. 19B shows the photoelectric conversion system when imaging of the front of the vehicle (an imaging range 1950) is performed. The vehicle information acquiring device 1920 sends an instruction to the photoelectric conversion system 1900 or the imaging device 1910. According to such a configuration, accuracy of ranging can be further improved.

While an example of controlling a vehicle so as to prevent a collision with another vehicle has been described above, the photoelectric conversion system can also be applied to controlling automated driving so that the vehicle follows another vehicle, controlling automated driving so that the vehicle stays within a lane, and the like. In addition, the photoelectric conversion system is not limited to a vehicle such as an automobile and can also be applied to a moving body (moving device) such as a ship, an airplane, or an industrial robot. The moving body includes one of or both of a driving force generating unit that generates a driving force mainly used for movement of the moving body and a rotating member that is mainly used for movement of the moving body. The driving force generating unit can be an engine, a motor, or the like. The rotating member can be a tire, a wheel, a screw of a ship, a propeller of a flight vehicle, or the like. Moreover, besides moving bodies, the photoelectric conversion system can be applied to a wide variety of devices that utilize object recognition such as an intelligent transportation system (ITS).

### Fifth Embodiment

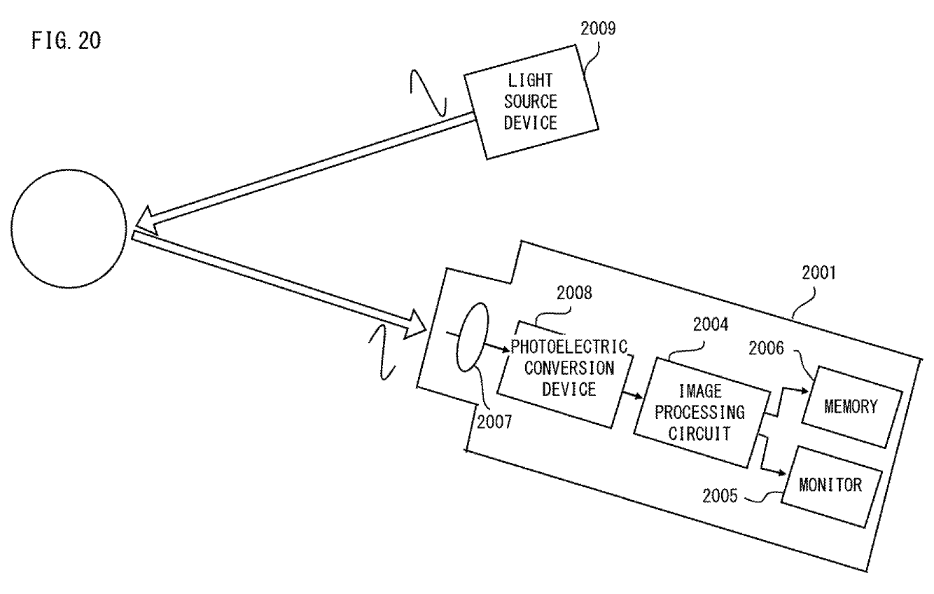

A photoelectric conversion system according to the present embodiment will be described with reference to FIG. 20. FIG. 20 is a block diagram showing a configuration example of a distance image sensor that is the photoelectric conversion system according to the present embodiment.

As shown in FIG. 20, a distance image sensor 2001 is configured to include an optical system 2007, a photoelectric conversion device 2008, an image processing circuit 2004, a monitor 2005, and a memory 2006. In addition, the distance image sensor 2001 is capable of acquiring a distance image in accordance with a distance to a subject by receiving light (modulated light or pulsed light) emitted toward the subject from a light source device 2009 and reflected by a surface of the subject.

The optical system 2007 is configured with one or a plurality of lenses and guides image light (incident light) from the subject to the photoelectric conversion device 2008 and forms an image on a light-receiving surface (a sensor unit) of the photoelectric conversion device 2008.

The image processing circuit 2004 performs image processing for constructing a distance image based on the distance signal supplied from the photoelectric conversion device 2008. In addition, a distance image (image data) obtained by the image processing is supplied to and displayed by the monitor 2005 or supplied to and stored (recorded) in the memory 2006.

With the distance image sensor 2001 configured as described above, applying one of the photoelectric conversion devices described above enables, for example, a more accurate distance image to be acquired due to an improvement in ranging accuracy.

### Sixth Embodiment

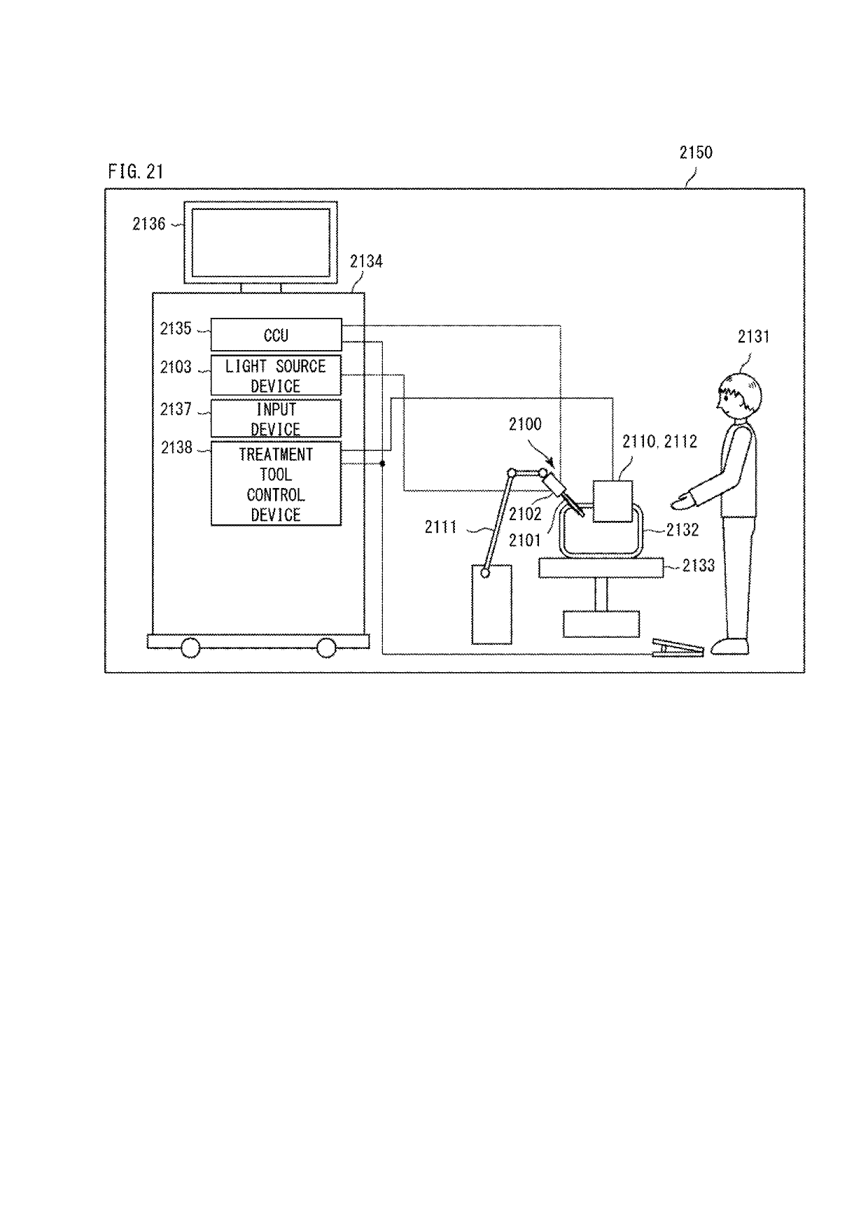

A photoelectric conversion system according to the present embodiment will be described with reference to FIG. 21. FIG. 21 is a diagram showing an example of a schematic configuration of an endoscopic surgery system that is the photoelectric conversion system according to the present embodiment.

FIG. 21 illustrates a situation where a technician (a physician) 2131 is using an endoscopic surgery system 2150 to operate on a patient 2132 on a patient bed 2133. As illustrated, the endoscopic surgery system 2150 is constituted of an endoscope 2100, a surgical instrument 2110, and a cart 2134 mounted with various devices for an endoscopic surgery.

The endoscope 2100 is constituted of a lens barrel 2101 of which a region with a predetermined length from a distal end is to be inserted into a body cavity of the patient 2132 and a camera head 2102 connected to a base end of the lens barrel 2101. While the illustrated example features the endoscope 2100 being configured as a so-called rigid scope having a rigid lens barrel 2101, alternatively, the endoscope 2100 may be configured as a so-called flexible scope having a flexible lens barrel.

An opening into which an objective lens is fitted is provided at the distal end of the lens barrel 2101. A light source device 2103 is connected to the endoscope 2100, and light generated by the light source device 2103 is guided to the distal end of the lens barrel 2101 by a light guide provided so as to extend inside the lens barrel and emitted toward an observation object inside a body cavity of the patient 2132 via the objective lens. It should be noted that the endoscope 2100 may be a forward-viewing endoscope, an oblique-viewing endoscope, or a side-viewing endoscope.

An optical system and a photoelectric conversion device are provided inside the camera head 2102 and reflected light (observation light) from the observation object is collected to the photoelectric conversion device by the optical system. The observation light is photoelectrically converted by the photoelectric conversion device and an electric signal corresponding to the observation light or, in other words, an image signal corresponding to an observed image is generated. As the photoelectric conversion device, the photoelectric conversion device according to any one of the embodiments described above can be used. The image signal is transmitted to a Camera Control Unit (CCU) 2135 as RAW data.

The CCU 2135 is constituted of a CPU (Central Processing Unit), a GPU (Graphics Processing Unit), or the like and comprehensively controls operations of the endoscope 2100 and a display device 2136. In addition, the CCU 2135 receives an image signal from the camera head 2102 and subjects the image signal to various kinds of image processing for displaying an image based on the image signal such as development processing (demosaicing).

Under control exerted by the CCU 2135, the display device 2136 displays an image based on the image signal subjected to image processing by the CCU 2135. The light source device 2103 is constituted of a light source such as an LED (Light-Emitting Diode) and supplies the endoscope 2100 with irradiation light used when photographing a surgical site or the like.

An input device 2137 is an input interface with respect to the endoscopic surgery system 2150. A user can input various kinds of information and input instructions to the endoscopic surgery system 2150 via the input device 2137.

A treatment tool control device 2138 controls drive of an energy treatment tool 2112 for cauterizing or incising tissue, sealing a blood vessel, or the like. The light source device 2103 that supplies the endoscope 2100 with irradiation light when photographing a surgical site can be constituted of a white light source constituted of an LED, a laser light source, or a combination thereof. When the white light source is constituted of a combination of RGB laser light sources, since output intensity and an output timing of each color (each wavelength) can be controlled with high accuracy, white balance of a captured image can be adjusted in the light source device 2103. In addition, in this case, an image corresponding to each of RGB can be captured in a time-divided manner by having an observation object be irradiated with laser light from each of the RGB laser light sources in a time-divided manner and controlling drive of an imaging element of the camera head 2102 in synchronization with the irradiation timing. According to this method, a color image can be obtained without having to provide the imaging element with a color filter.

In addition, drive of the light source device 2103 may be controlled such that intensity of output light changes at predetermined intervals. By controlling drive of imaging elements of the camera head 2102 in synchronization with a timing at which the intensity of light changes to acquire images in a time-divided manner and compositing the images, an image with a high dynamic range that is free of so-called blocked-up shadows and blown-out highlights can be generated.

Furthermore, the light source device 2103 may be configured to be capable of supplying light in a predetermined wavelength band that accommodates special light observation. In special light observation, for example, wavelength dependence of absorption of light by body tissue is utilized. Specifically, predetermined tissue such as a blood vessel of a superficial portion of a mucous membrane is photographed with high contrast by irradiating light with a narrower band than irradiation light during normal observation (in other words, white light). Alternatively, in special light observation, fluorescent observation may be performed in which an image is obtained using fluorescent light generated by irradiating excitation light. In fluorescent observation, body tissue may be irradiated with excitation light and fluorescent light from the body tissue can be observed, a reagent such as indocyanine green (ICG) can be locally injected into body tissue and the body tissue can be irradiated with excitation light corresponding to a fluorescent wavelength of the reagent to obtain a fluorescent image, and the like. The light source device 2103 may be configured to be capable of supplying narrow-band light and/or excitation light that accommodates such special light observation.

### Seventh Embodiment

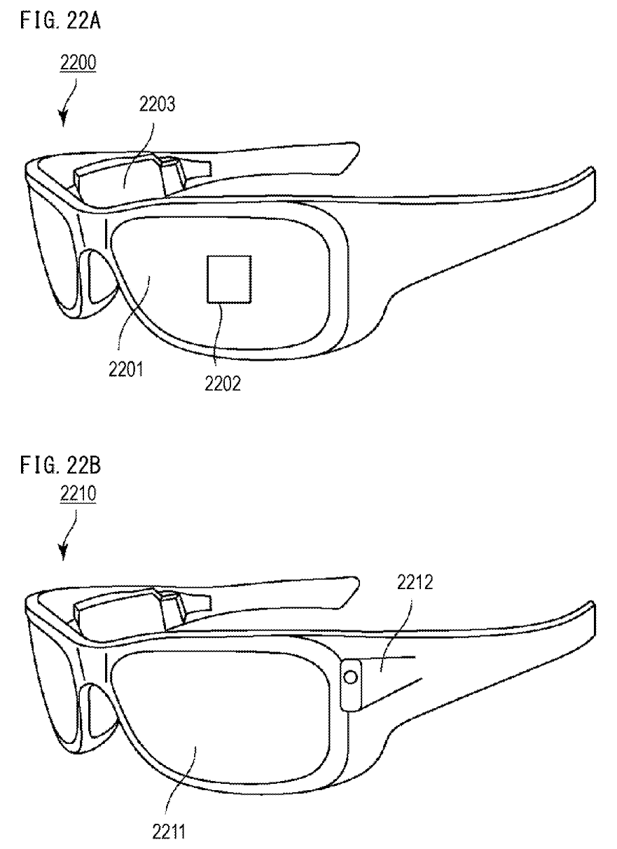

A photoelectric conversion system according to the present embodiment will be described with reference to FIGS. 22A and 22B. FIG. 22A illustrates eyeglasses 2200 (smart glasses) that is the photoelectric conversion system according to the present embodiment. The eyeglasses 2200 have a photoelectric conversion device 2202. The photoelectric conversion device 2202 is the photoelectric conversion device (imaging device) according to any one of the embodiments described above. In addition, a display device including a light-emitting device such as an OLED or an LED may be provided on a rear surface side of a lens 2201. There may be one or a plurality of photoelectric conversion devices 2202. Alternatively, a plurality of types of photoelectric conversion devices may be used in combination. An arrangement position of the photoelectric conversion device 2202 is not limited to that shown in FIG. 22A.

The eyeglasses 2200 further include a control device 2203. The control device 2203 functions as a power source that supplies power to the photoelectric conversion device 2202 and the display device described above. In addition, the control device 2203 controls operations of the photoelectric conversion device 2202 and the display device. An optical system for collecting light to the photoelectric conversion device 2202 is formed in the lens 2201.

FIG. 22B illustrates eyeglasses 2210 (smart glasses) according to one application example. The eyeglasses 2210 include a control device 2212 and the control device 2212 is mounted with a photoelectric conversion device that corresponds to the photoelectric conversion device 2202 and a display device. An optical system for projecting light emitted from the photoelectric conversion device inside the control device 2212 and the display device is formed in the lens 2211 and an image is projected onto the lens 2211. The control device 2212 functions as a power source that supplies power to the photoelectric conversion device and the display device and, at the same time, controls operations of the photoelectric conversion device and the display device. The control device may have a line-of-sight detecting unit that detects a line-of-sight of a wearer. Infrared light may be used to detect a line-of-sight. An infrared light-emitting unit emits infrared light to the eyes of a user who is looking at a display image. A picked-up image of the eyes can be obtained by having an imaging unit including a light-receiving element detect reflected light from the eyes of emitted infrared light. Providing reducing means that reduces light from the infrared light-emitting unit to the display unit in a plan view enables a decline in image quality to be mitigated.

A line-of-sight of the user with respect to a display image can be detected from a picked-up image of eyes obtained by imaging with infrared light. Any known method can be applied to line-of-sight detection using a picked-up image of the eyes. For example, a line-of-sight detection method based on a Purkinje image due to reflection of irradiation light by the cornea can be used.

More specifically, line-of-sight detection processing based on a pupil-corneal reflection method is performed. Using the pupil-corneal reflection method, a line-of-sight of a user is detected by calculating a line-of-sight vector that represents an orientation (a rotation angle) of the eyes based on an image of a pupil included in a picked-up image of the eyes and a Purkinje image. The display device according to the present embodiment may have a photoelectric conversion device including a light-receiving element and a display image of the display device may be controlled based on line-of-sight information of the user from the photoelectric conversion device.

Specifically, the display device determines, based on the line-of-sight information, a first field-of-view region which the user focuses on and a second field-of-view region other than the first field-of-view region. The first field-of-view region and the second field-of-view region may be determined by the control device of the display device or regions determined by an outside control device may be received as the first field-of-view region and the second field-of-view region. In a display region of the display device, a display resolution of the first field-of-view region may be controlled to be higher than a display resolution of the second field-of-view region. In other words, the resolution of the second field-of-view region may be set lower than that of the first field-of-view region.

In addition, the display region may have a first display region and a second display region that differs from the first display region, and a region with high priority may be determined from the first display region and the second display region based on line-of-sight information. The first display region and the second display region may be determined by the control device of the display device or regions determined by an outside control device may be received as the first display region and the second display region. A resolution of a region with high priority may be controlled to be higher than a resolution of a region other than the region with high priority. In other words, a resolution of a region of which a priority is relatively low can be lowered.

It should be noted that an AI (Artificial Intelligence) may be used to determine the first field-of-view region and a region with high priority. The AI may be a model configured to use an image of the eyes and a direction actually viewed by the eyes in the image as teacher data to estimate, from the image of the eyes, an angle of a line-of-sight and a distance to an object ahead of the line-of-sight. An AI program may be included in the display device, the photoelectric conversion device, or an external device. When the external device includes an AI program, an inference result by an AI is sent to the display device via communication.

Display control based on visual recognition and detection can be preferably applied to smart glasses further including a photoelectric conversion device that captures images of the outside. The smart glasses are capable of displaying captured external information in real-time.

### Eighth Embodiment

The photoelectric conversion devices and the photoelectric conversion systems described above can be applied to, for example, electronic devices such as so-called smartphones and tablets.

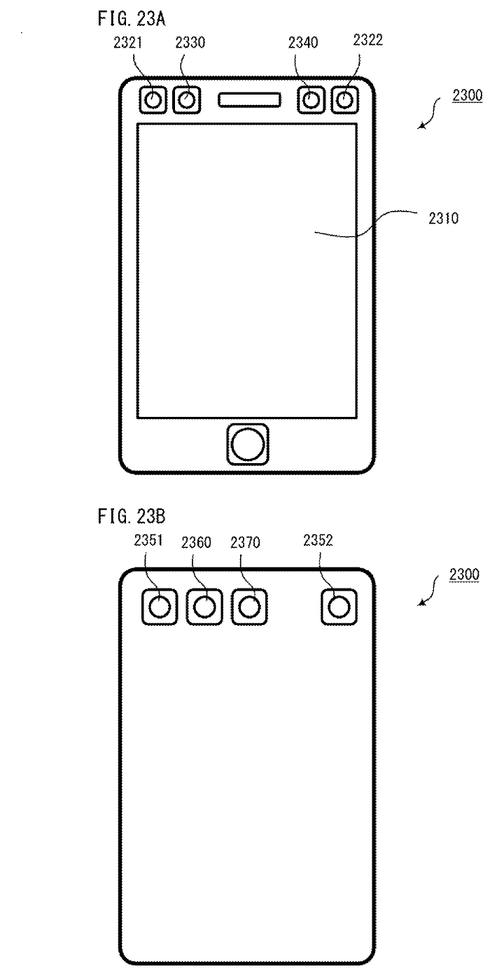

FIGS. 23A and 23B are diagrams showing an example of an electronic device 2300 to which a photoelectric conversion device is mounted. FIG. 23A shows a front surface side of the electronic device 2300 and FIG. 23B shows a rear surface side of the electronic device 2300.

As shown in FIG. 23A, a display 2310 that displays an image is arranged at a center of the front surface of the electronic device 2300. In addition, front cameras 2321 and 2322 that use the photoelectric conversion device, an IR light source 2330 that emits infrared light, and a visible light source 2340 that emits visible light are arranged along an upper side of the front surface of the electronic device 2300.

Furthermore, as shown in FIG. 23B, rear cameras 2351 and 2352 that use the photoelectric conversion device, an IR light source 2360 that emits infrared light, and a visible light source 2370 that emits visible light are arranged along an upper side of the rear surface of the electronic device 2300.

In the electronic device 2300 configured as described above, by applying the photoelectric conversion device described above, for example, an image with higher quality can be captured and a distance to an object can be measured with high accuracy. Note that the photoelectric conversion device can be applied to other electronic devices such as an infrared sensor, a ranging sensor using an active infrared light source, a security camera, and a personal authentication camera or a biometric camera. As a result, accuracy and performance of such electronic devices can be improved.

### Ninth Embodiment

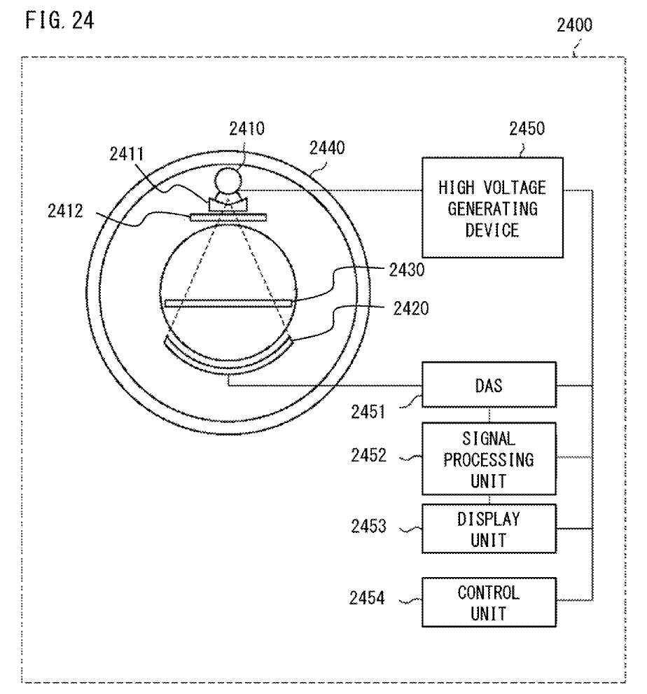

FIG. 24 is a block diagram of an X-ray CT device according to the present embodiment. The photoelectric conversion devices and the photoelectric conversion systems described above can be applied to a detector of the X-ray CT device. An X-ray CT device 2400 according to the present embodiment includes an X-ray generating unit 2410, a wedge 2411, a collimator 2412, an X-ray detecting unit 2420, and a top plate 2430. Furthermore, the X-ray CT device 2400 includes a rotating frame 2440, a high voltage generating device 2450, a data collection device (DAS: Data Acquisition System) 2451, a signal processing unit 2452, a display unit 2453, and a control unit 2454.

The X-ray generating unit 2410 is constituted of, for example, a vacuum tube that generates X-rays. A high voltage from the high voltage generating device 2450 and a filament current are supplied to the vacuum tube of the X-ray generating unit 2410. An X-ray is generated as thermions are radiated from a cathode (filament) toward an anode (target).

The wedge 2411 is a filter that adjusts an X-ray dosage radiated from the X-ray generating unit 2410. The wedge 2411 attenuates the X-ray dosage so that X-rays radiated from the X-ray generating unit 2410 toward the object are distributed as determined in advance. The collimator 2412 is constituted of a lead plate or the like that narrows down an irradiation range of the X-rays having passed through the wedge 2411. An X-ray generated by the X-ray generating unit 2410 is molded into a cone beam shape via the collimator 2412 and radiated to the object on the top plate 2430.

The X-ray detecting unit 2420 is constructed by using the photoelectric conversion device or the photoelectric conversion system described above. The X-ray detecting unit 2420 detects an X-ray having passed through the object from the X-ray generating unit 2410 and outputs a signal corresponding to the X-ray dosage to the DAS 2451.

The rotating frame 2440 has an annular shape and is configured to be rotatable. The X-ray generating unit 2410 (the wedge 2411 and the collimator 2412) and the X-ray detecting unit 2420 are arranged so as to oppose each other inside the rotating frame 2440. The X-ray generating unit 2410 and the X-ray detecting unit 2420 are rotatable together with the rotating frame 2440.

The high voltage generating device 2450 includes a boost circuit and outputs a high voltage to the X-ray generating unit 2410. The DAS 2451 includes an amplifier circuit and an A/D converter circuit and outputs a signal from the X-ray detecting unit 2420 as digital data to the signal processing unit 2452.

The signal processing unit 2452 includes a CPU (Central Processing Unit), a ROM (Read Only Memory), and a RAM (Random Access Memory) and is capable of executing image processing of digital data and the like. The display unit 2453 includes a flat display device or the like and is capable of displaying an X-ray image. The control unit 2454 includes a CPU, a ROM, and a RAM and controls operations of the entire X-ray CT device 2400.

### Tenth Embodiment

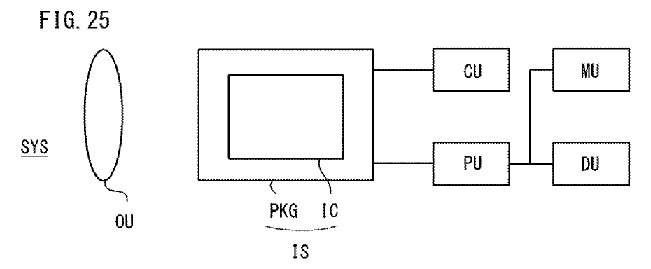

A photoelectric conversion system according to a tenth embodiment will be described with reference to FIG. 25. FIG. 25 is a block diagram showing a schematic configuration of an imaging system SYS that is the photoelectric conversion system according to the eleventh embodiment. The imaging system SYS includes at least the photoelectric conversion device according to any one of the embodiments described above and a signal processing unit that processes signals output from the photoelectric conversion device.

The imaging system SYS is an information terminal that includes a camera and a photography function. The imaging system SYS is constructed using an imaging device IS. The imaging device IS can further include a package PKG that houses an imaging device IC. The package PKG can include a substrate on which the imaging device IC is fixed and a lid body that opposes the imaging device IC. The package PKG can include a connecting member (a member that connects a terminal provided on the substrate and a terminal provided on the imaging device IC) to each other. The imaging device IS can mount a plurality of the imaging devices IC to a common package PKG by arranging the imaging devices IC side by side. Alternatively, the imaging device IS can mount the imaging device IC and another semiconductor device IC to a common package PKG by stacking the imaging device IC and the semiconductor device IC on top of each other.

The imaging system SYS can include an optical system OU (optical device) that forms an image on the imaging device IS. In addition, the imaging system SYS can include at least any of a control device CU, a processing device PU, a display device DU, and a storage device MU. The control device CU controls the imaging device IS and the processing device PU processes a signal obtained from the imaging device IS. Furthermore, the display device DU displays an image obtained from the imaging device IS and the storage device MU stores the image obtained from the imaging device IS.

According to the present disclosure, in a photoelectric conversion device configured with a plurality of pixels corresponding to one microlens, the illuminance range in which a phase difference can be detected can be extended.

Although various devices have been described in the above-described embodiments, mechanical devices may be further provided. A mechanical device in a camera can drive the components of an optical system to perform zooming, focusing, and shutter operations. Alternatively, a mechanical device in a camera can move a photoelectric conversion device for a vibration-insulating operation.

Also, the device can be transportation equipment such as a vehicle, a ship, or a flying object. The mechanical device in transportation equipment can be used as a mobile device. Equipment as transportation equipment is suitable for transportation of a photoelectric conversion device and for assisting and/or automating the operation (maneuvering) by the photographing function. A processing device for assisting and/or automating the operation (maneuvering) can perform processing for operating a mechanical device as a mobile device on the basis of information obtained by the photoelectric conversion device.

Expressions such as "A or B", "at least one of A and B", "at least one of A and/or B", and "one or more of A and/or B" may be used herein. In this case, all possible combinations of enumerated items may be included unless explicitly defined otherwise. That is, it is understood that the expressions disclose all the cases in which at least one A is included, at least one B is included, and at least one A and at least one B are included. This applies similarly to a combination of three or more elements.

The embodiments described above may be appropriately modified without departing from the technical idea. Note that the disclosed content of the present specification includes not only the matters described herein, but also all matters understandable from the present specification and the accompanying drawings attached thereto. The disclosure in the present specification also includes a complement of the concepts described herein. That is, for example, if there is a description of "A is greater than B" in the present specification, even if a description of "A is not greater than B" is omitted, it can be said that the present specification discloses "A is not greater than B". This is because, when "A is greater than B" is described, it is assumed that "A is not greater than B" is considered.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-046643, filed March 21, 2025, which is hereby incorporated by reference herein in its entirety.

What is claimed is:

1. A photoelectric conversion device comprising:
a microlens; and
a plurality of pixels that share the microlens,
wherein the plurality of pixels include a first pixel having a first sensitivity, a second pixel having the first sensitivity, a third pixel having a second sensitivity different from the first sensitivity, and a fourth pixel having the second sensitivity,
the first pixel and the second pixel are arranged with point symmetry with respect to an optical axis of the microlens,
a phase difference is detected by using a pair of a signal output from the first pixel and a signal output from the second pixel, and
a phase difference is detected by using a pair of a signal output from the third pixel and a signal output from the fourth pixel.

2. The photoelectric conversion device according to claim 1, wherein the third pixel and the fourth pixel are arranged with point symmetry with respect to the optical axis of the microlens.

3. The photoelectric conversion device according to claim 1, wherein the plurality of pixels are arranged in a lattice pattern on a substrate on which the microlens and the plurality of pixels are disposed.

4. The photoelectric conversion device according to claim 1, wherein the plurality of pixels are arranged in a lattice pattern of M rows and N columns (M and N are natural numbers, M≠N).

5. The photoelectric conversion device according to claim 4, wherein the plurality of pixels are arranged in a lattice pattern of three rows and three columns.

6. The photoelectric conversion device according to claim 4, wherein the plurality of pixels are arranged in a lattice pattern of one row and five columns or a lattice pattern of five rows and one column.

7. The photoelectric conversion device according to claim 4, wherein the first pixel and the second pixel are disposed on a diagonal line of the lattice pattern, and the third pixel and the fourth pixel are disposed on a diagonal line of the lattice pattern.

8. The photoelectric conversion device according to claim 4, wherein the first pixel and the second pixel are disposed in a same row, and the third pixel and the fourth pixel are disposed in a same row.

9. The photoelectric conversion device according to claim 8, wherein the first pixel and the second pixel are disposed in a same column, and the third pixel and the fourth pixel are disposed in a same column.

10. The photoelectric conversion device according to claim 1, wherein the plurality of pixels include a fifth pixel having a third sensitivity different from the first sensitivity and the second sensitivity.

11. The photoelectric conversion device according to claim 10, wherein the fifth pixel is disposed at a position overlapping a center of the microlens in plan view.

12. The photoelectric conversion device according to claim 11, wherein the third sensitivity is higher than the first sensitivity and the second sensitivity.

13. The photoelectric conversion device according to claim 1, wherein the first pixel and the second pixel are arranged with point symmetry with respect to the optical axis of the microlens and line symmetry with respect to a straight line passing the optical axis.

14. A photoelectric conversion system comprising:
the photoelectric conversion device according to claim 1; and
a signal processing unit that processes a signal output by the photoelectric conversion device.

15. A photoelectric conversion system comprising:
the photoelectric conversion device according to claim 1; and
a signal processing unit that generates an image by using a signal output by the photoelectric conversion device.

16. A mobile body comprising the photoelectric conversion device according to claim 1,
wherein the mobile body includes a control unit that controls a movement of the mobile body by using a signal output by the photoelectric conversion device.

17. Equipment comprising:
the photoelectric conversion device according to claim 1; and
at least any of an optical device corresponding to the photoelectric conversion device;
a control device that controls the photoelectric conversion device;
a processing device that processes a signal output from the photoelectric conversion device;
a display device that displays information obtained by the photoelectric conversion device;
a storage device that stores information obtained by the photoelectric conversion device; and
a mechanical device that operates on the basis of the information obtained by the photoelectric conversion device.
